(19) United States
(12) Patent Application Publication
(10) Pub. No.: US 2025/0349604 A1
(43) Pub. Date: Nov. 13, 2025

(54) SEMICONDUCTOR DEVICE AND METHOD FOR FORMING THE SAME

(71) Applicant: Winbond Electronics Corp., Taichung City (TW)

(72) Inventors: Shih-Chien LIN, Kaohsiung City (TW); Yi-Tsung TSAI, Taichung City (TW)

(21) Appl. No.: 19/174,196

(22) Filed: Apr. 9, 2025

(30) Foreign Application Priority Data
May 13, 2024 (TW) 113117569

(51) Int. Cl. H01L 21/768; H01L 23/528; H01L 23/532

(52) U.S. Cl. CPC H01L 21/7682; H01L 21/76829; H01L 23/5283; H01L 23/53295

(57) ABSTRACT

A semiconductor device is provided. The semiconductor device includes a substrate, conductive units, and a plurality of gaps. The conductive units are disposed on the substrate. Each conductive unit includes: a conductive structure and a pair of spacer structures. Each spacer structure comprises a first spacer layer disposed on the substrate, a second spacer layer disposed on the first spacer layer, and a third spacer layer disposed on the second spacer layer. The first spacer layer, the second spacer layer and the third spacer layer each comprise different materials. The conductive structure is disposed on the substrate. The spacer structures are disposed along both sides of the conductive structure. The gaps are disposed between each of the conductive units.

### CROSS REFERENCE TO RELATED APPLICATIONS

This Application claims priority of Taiwan Patent Application No. 113117569, filed on May 13, 2024, the entirety of which is incorporated by reference herein.

### BACKGROUND OF THE INVENTION

### Field of the Invention

The present invention relates to a semiconductor device, and in particular it relates to a semiconductor device and a method for forming the same that improves upon the problem of short-circuiting between bit lines.

### Description of the Related Art

As the size of electronic products and semiconductor devices continues to shrink, many challenges arise. For example, in the process of manufacturing flash memory, bit lines are prone to short-circuiting. Also, the resist-capacitor delay (RC delay) increases, which causes the performance of the flash memory to degrade. Therefore, the industry still needs to improve its method of manufacturing flash memory to overcome the problems caused by shrinking device size.

### BRIEF SUMMARY OF THE INVENTION

Some embodiments of the present disclosure provide a semiconductor device. The semiconductor device includes a substrate, a plurality of conductive units, and a plurality of air gaps. The conductive units are disposed on the substrate. Each conductive unit includes a conductive structure and a pair of spacer structures. Each spacer structure comprises a first spacer layer disposed on the substrate, a second spacer layer disposed on the first spacer layer, and a third spacer layer disposed on the second spacer layer. The first spacer layer, the second spacer layer and the third spacer layer each comprise different materials. The conductive structure is disposed on the substrate. The spacer structures are disposed along both sides of the conductive structure. The air gap is disposed between each conductive unit.

Some embodiments of the present disclosure also provide a method for forming a semiconductor device. The method of forming a semiconductor device includes providing a substrate. The method includes sequentially forming a spacer stack layer with a first spacer predetermined layer, a second spacer predetermined layer and a third spacer predetermined layer on the substrate. The method includes patterning the spacer stack layer to form a plurality of spacer predetermined structures and a plurality of trenches. The method includes forming a plurality of conductive structures in the trenches. The method includes patterning the spacer predetermined structures to form a plurality of spacer structures on the sidewalls of the conductive structures. The patterning the spacer predetermined structures includes replacing the third spacer predetermined layer with a plurality of fourth spacer layers, and patterning the second spacer predetermined layer and the first spacer predetermined layer using the fourth spacer layers as masks. After forming the spacer structures, a barrier layer is formed on the substrate, wherein the barrier layer includes an air gap.

### BRIEF DESCRIPTION OF THE DRAWINGS

The present invention can be more fully understood by reading the subsequent detailed description and examples with references made to the accompanying drawings, wherein:

FIGS. 1-8 are cross-sectional views showing formation of a semiconductor device at different stages according to some embodiments of the present invention.

### DETAILED DESCRIPTION OF THE INVENTION

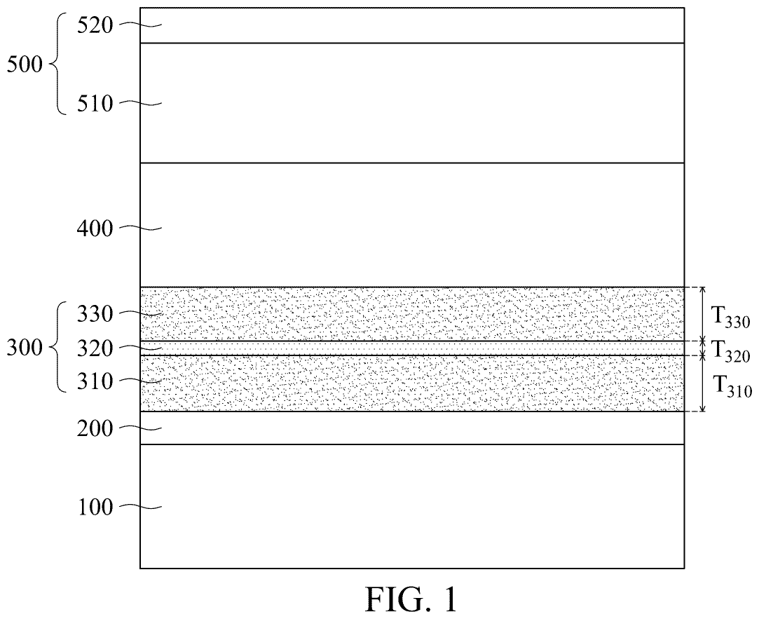

First, please refer to FIG. 1, a substrate 100 is provided.

In some embodiments, the substrate 100 may be an element semiconductor substrate, such as a silicon substrate or a germanium substrate; or a compound semiconductor substrate, such as a silicon carbide substrate, a gallium arsenide substrate, a gallium phosphide substrate, an indium phosphide substrate, an indium arsenide substrate and/or indium antimonide substrate; or an alloy semiconductor, such as SiGe, GaAsP, AlInAs, AlGaAs, GaInAs, GaInP, GaInAsP. In some embodiments, substrate 100 may be a semiconductor-on-insulator substrate. In this embodiment, the semiconductor device provided by the embodiment of the present invention may be used as a contact connected to the substrate 100 in the front-end process.

In other embodiments, the substrate 100 may include a semiconductor substrate and a dielectric layer, a metal layer, a via hole, a contact, a memory unit (such as a floating gate and a control gate of a flash memory) formed thereon. The semiconductor device provided in this embodiment may be used as a connector between the metal layers in the back-end process.

A dielectric layer 200 is formed on the substrate 100. The dielectric layer 200 may later serve as an etch stop layer. In some embodiments, the dielectric layer 200 includes a dielectric material, which may be an oxide, a nitride, an oxynitride, or a combination of the foregoing, such as silicon oxide, silicon nitride, silicon oxynitride, high dielectric constant (high-k) materials, or a combination of the above. In some embodiments, the formation of the dielectric layer 200 may include a chemical vapor deposition (CVD) process, a physical vapor deposition (PVD) process, or an atomic layer deposition (ALD) process.

A spacer stack layer 300 is formed on the dielectric layer 200. In some embodiments, the spacer stack layer 300 includes a first spacer predetermined layer 310, a second spacer predetermined layer 320, and a third spacer predetermined layer 330

The first spacer predetermined layer 310, the second spacer predetermined layer 320, and the third spacer predetermined layer 330 may respectively have a thickness T₃₁₀, a thickness T₃₂₀, and a thickness T₃₃₀.

In some embodiments, the greater the thickness T₃₁₀, the greater the support for the subsequently formed conductive structure. The greater the thickness T330, the greater the subsequent air gap formed. In some embodiments, the ratio of thickness T₃₁₀ to thickness T₃₃₀ may be between 1:0.6-1:1.4, such as 1:1. For example, when the ratio of the thickness T₃₁₀ to the thickness T₃₃₀ is 1:1, the first spacer predetermined layer 310 and the third spacer predetermined layer 330 have the same thickness. By being within the above range, the supporting force and size of air gap of the subsequently formed spacer structure may be optimized.

In some embodiments, the first spacer predetermined layer 310, the second spacer predetermined layer 320, and the third spacer predetermined layer 330 may include dielectric materials, semiconductor materials, and the like. In the embodiment of the present invention, the first spacer predetermined layer 310 and the third spacer predetermined layer 330 include the same material, such as a semiconductor material; the second predetermined spacer layer 320 includes a dielectric material. The semiconductor material may be doped or undoped polycrystalline silicon, or the like. The dielectric material may be nitride, such as silicon nitride. In some embodiments, the formation of the spacer stack layer 300 may include a deposition process similar to that described above.

A hard mask layer 400 and an anti-reflective coating 500 are formed on the spacer stack layer 300, which are used for subsequent patterning of the spacer stack layer 300.

In some embodiments, the hard mask layer 400 includes doped or undoped polysilicon.

In some embodiments, the anti-reflective coating 500 may prevent reflection of the underlying film layer during exposure and facilitate pattern transfer. In some embodiments, the anti-reflective coating 500 may include a single layer, a double layer, or a multi-layer structure. For example, in FIG. 1, the anti-reflective coating 500 has a double-layer structure and includes a first anti-reflective coating 510 and a second anti-reflective coating 520. In some embodiments, the anti-reflective coating 500 may include spin-on carbon (SOC), silicon oxynitride (SiON), or a combination of the foregoing. For example, in FIG. 1, the first anti-reflective coating 510 is spin-coated carbon (SOC), the second anti-reflective coating 520 is silicon oxynitride (SiON), and the first anti-reflective coating 510 is thicker than the second anti-reflective coating 520.

In some embodiments, the hard mask layer 400 and the anti-reflective coating 500 may include a deposition process similar to that described above.

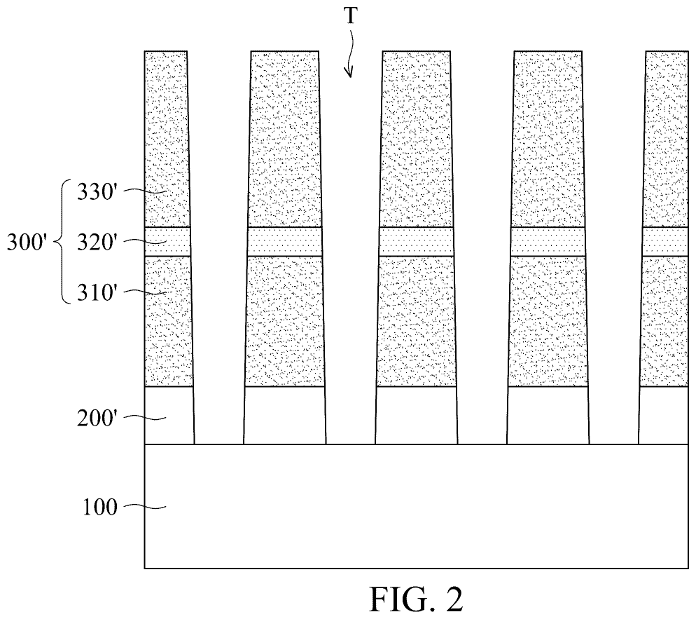

Next, a patterned photoresist (not shown) is used to pattern the spacer stack layer 300 and the dielectric layer 200, and the patterned photoresist, anti-reflective coating 500 and hard mask layer 400 are removed. That is, as shown in FIG. 2, the spacer stack layer 300 is patterned to form a plurality of spacer predetermined structures 300′ and a plurality of trenches T. Moreover, the dielectric layer 200 is also patterned at the same time, and the trench T is extended to contact the substrate 100.

Here, the first spacer predetermined layer 310, the second spacer predetermined layer 320 and the third spacer predetermined layer 330 are denoted as the first spacer predetermined layer 310′, the second spacer predetermined layer 320′ and the third spacer define layer 330′ after patterning.

In some embodiments, patterning the spacer stack layer 300 and the dielectric layer 200 includes a patterning process. The patterning process includes a photolithography process and an etching process. The photolithography process includes photoresist coating, baking before exposure, exposure using a mask, development, and the like. The etching process includes an anisotropic etching process, such as a dry etching process.

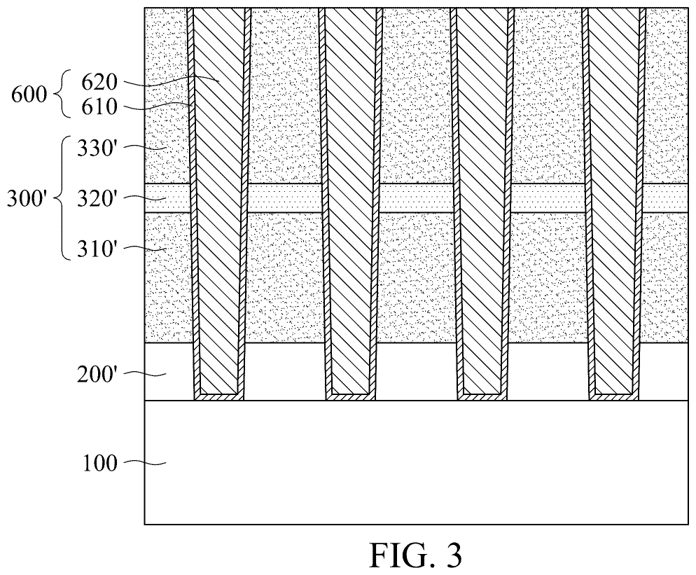

Next, a plurality of conductive structures 600 are formed in the trenches T, as shown in FIG. 3. That is, the conductive structure 600 penetrates through the dielectric layer 200′ and contacts the substrate 100. In some embodiments, the conductive structure 600 may include a metal layer 620 and a block layer 610 surrounding the metal layer 620. The block layer 610 may prevent the substance in the metal layer 620 from diffusing to the spacer predetermined structure 300′. In embodiments of the present invention, the conductive structure 600 may be used as a connector between metal layers in the back-end process.

In some embodiments, the block layer 610 may include metal, metal alloy, metal nitride, other conductive materials, or combinations thereof. Specifically, the block layer 610 may be titanium (Ti), tantalum (Ta), titanium nitride (TiN), tantalum nitride (TaN), or combinations thereof. In some embodiments, the metal layer 620 may be a conductive material, which may include metal, metal alloy, or the like. Specifically, the metal layer 620 may be tungsten, aluminum, copper, gold, silver or a combination of the above.

In some embodiments, the formation of the conductive structure 600 may include a deposition process similar to that described above. For example, after depositing the block layer 610 in the trench T, the metal layer 620 is then deposited on the block layer 610. Next, a planarization process is used to make the block layer 610 and the metal layer 620 coplanar with the top surface of the spacer predetermined structure 300′.

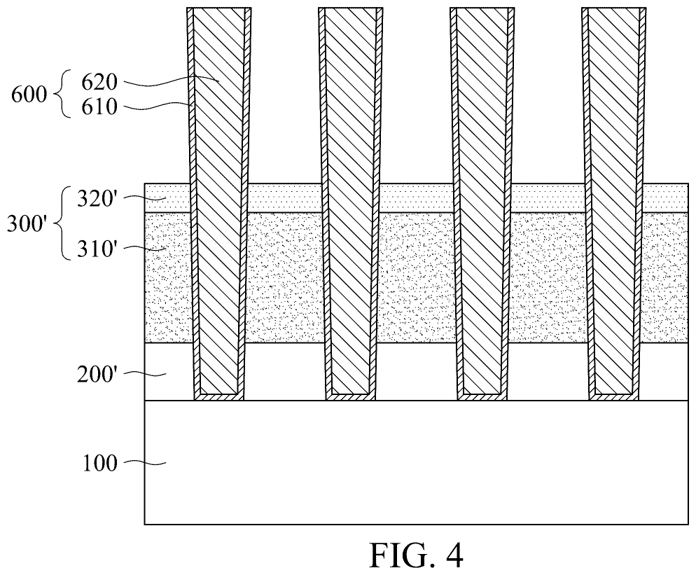

Next, the spacer predetermined structure 300′ is patterned to form a plurality of spacer structures 300″ on the sidewalls of the conductive structure 600, as shown in FIG. 4-7. Details are as follows.

As shown in FIG. 4, the third spacer predetermined layer 330′ in the predetermined spacer structure 300′ is removed. In some embodiments, the third predetermined spacer layer 330′ may include an etching process similar to the foregoing, such as an anisotropic dry etching process. In the embodiment of the present invention, since the dry etching process (for example, using HBr as an etchant) may have a high etching selectivity ratio for the third spacer predetermined layer 330′ including a semiconductor material (for example, polycrystalline silicon), the second spacer predetermined layer 320′ is used as an etch stop layer, and the third predetermined spacer layer 330′ is removed while the conductive structure 600 is substantially not damaged.

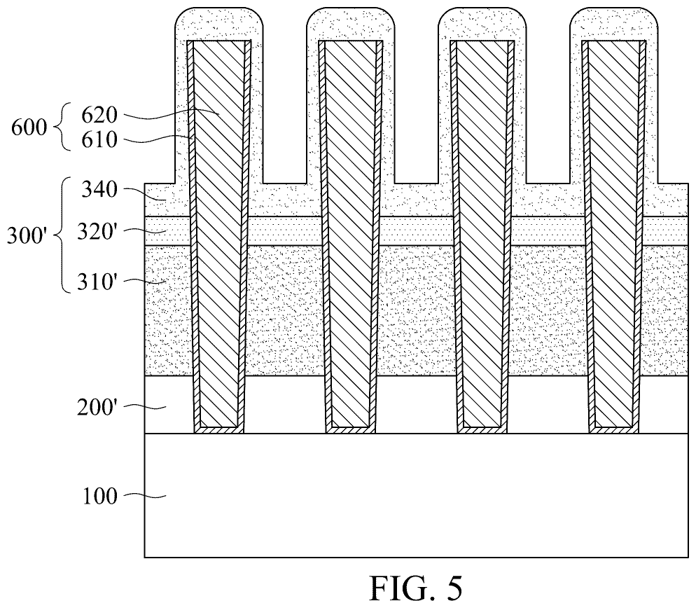

As shown in FIG. 5, a fourth spacer material layer 340 is conformally formed on the second spacer predetermined layer 320′ and the conductive structure 600. It should be noted that the thickness of the fourth spacer material layer 340 is one of the factors that determines the size of the subsequently formed air gap. For example, the thicker the fourth spacer material layer 340 is, the smaller the air gap formed subsequently will tend to be.

In some embodiments, the fourth spacer material layer 340 includes a dielectric material, such as an oxide (silicon oxide). By using oxide as the material of the fourth spacer material layer 340, the embodiments of the present invention may make it easier to seal the subsequently formed barrier layer (that is, it will be easier to form an air gap later). It should be noted that the fourth spacer material layer 340 and the second spacer predetermined layer 320′ are made of different materials, so that the second spacer predetermined layer 320′ may be used as an etch stop layer in the subsequent etching process. In some embodiments, the formation of the fourth spacer material layer 340 includes a deposition process similar to that described above.

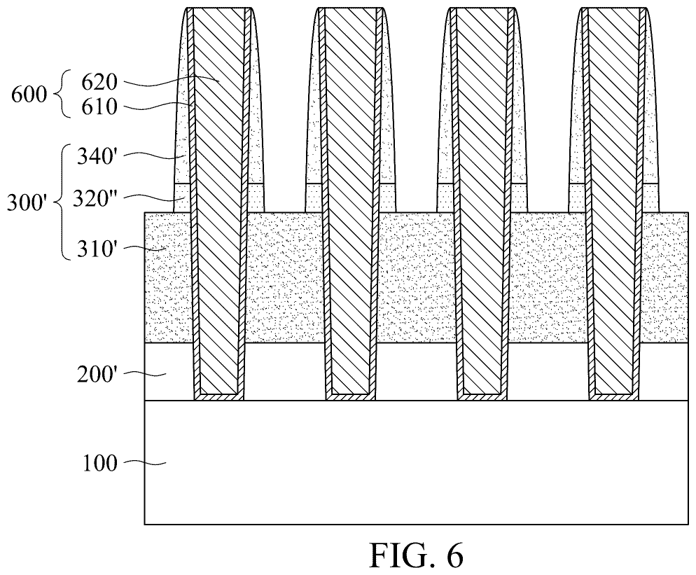

As shown in FIG. 6, the fourth spacer material layer 340 on the second spacer predetermined layer 320′ and on the top surface of the conductive structure 600 is removed to form a plurality of fourth spacer layers 340′. In some embodiments, the fourth spacer layer 340′ has a width that is narrow at the top and wide at the bottom, and becomes wider toward the substrate 100. That is, the width of the top surface of the fourth spacer layer 340′ is smaller than the width of the bottom surface of the fourth spacer layer 340′.

In some embodiments, the removal of the fourth spacer material layer 340 may include an etching process similar to the above.

As shown in FIG. 6, the first spacer predetermined layer 310 is used as an etch stop layer, and the fourth spacer layer 340′ is used as an etch mask to etch the second spacer predetermined layer 320′. Here, the etched second spacer predetermined layer 320′ is denoted as a second spacer layer 320″. In some embodiments, the etching of the second spacer predetermined layer 320′ may include the aforementioned etching process.

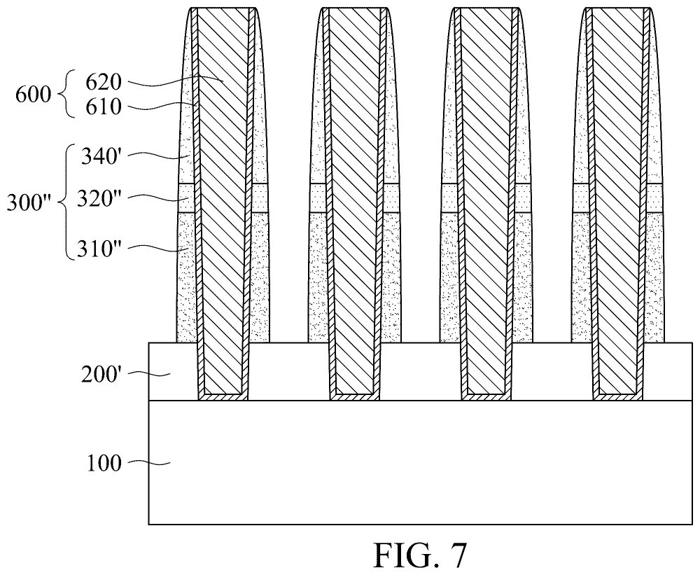

As shown in FIG. 7, using the fourth spacer layer 340′ as a mask, the first spacer predetermined layer 310′ is etched. Here, the etched first spacer predetermined layer 310′ is denoted as a first spacer layer 310″. The etching of the first spacer predetermined layer 310 may include an etching process similar to that described above.

In detail, since the dry etching process (for example, using HBr as an etchant) may have a high etching selectivity for the first spacer predetermined layer 310′ including a semiconductor material (for example, polycrystalline silicon), the conductive structure 600 may be substantially not damaged. In this case, the dielectric layer 200 is used as an etch stop layer and the fourth spacer layer 340′ is used as an etch mask to etch the first spacer predetermined layer 310′. Moreover, it may also be ensured that the first spacer predetermined layer 310′ is cut off, which facilitates the subsequent formation of air gaps.

Following the above, the spacer structure 300″ including the first spacer layer 310″, the second spacer layer 320″ and the fourth spacer layer 340′ is formed on both sides of the conductive structure 600. In some embodiments, the spacer structure 300′ is wing-like.

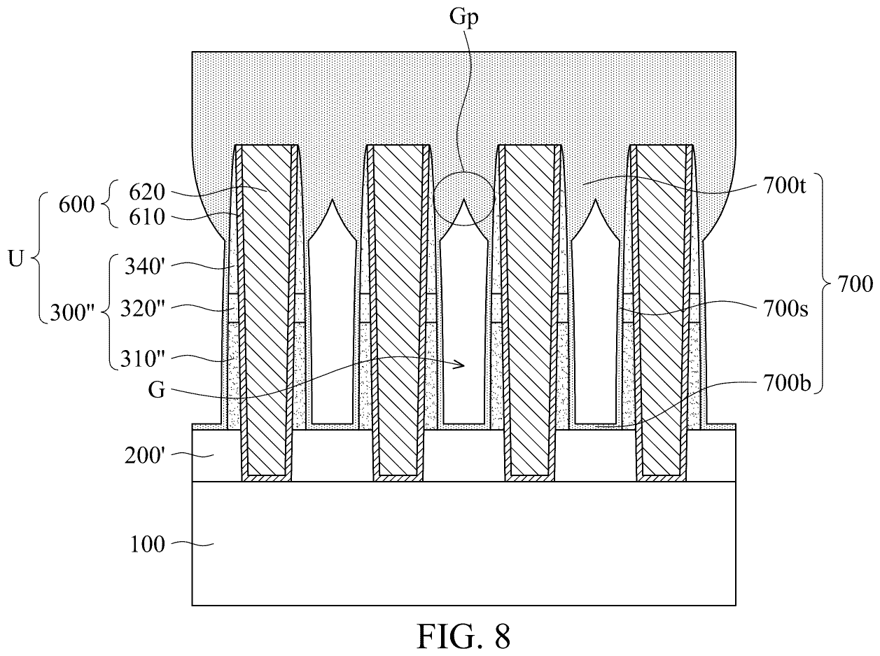

Next, a barrier layer 700 is formed on the substrate 100 and on the spacer structure 300″, as shown in FIG. 8. The barrier layer 700 has poor step coverage and is used to electrically isolate the conductive structure 600. In some embodiments, the barrier layer 700 includes a top barrier layer 700t, a side barrier layer 700s, and a bottom barrier layer 700b. Furthermore, the air gap G is surrounded by the top barrier layer 700t, the side barrier layer 700s, and the bottom barrier layer 700b.

In some embodiments, the barrier layer 700 may include a dielectric material, such as oxide or nitride, such as silicon carbide nitride (SiCN). In the case where the conductive structure 600 includes copper, the barrier layer 700 preferably uses nitride to prevent copper from drilling in and affecting the performance of the semiconductor device.

In some embodiments, the formation of the barrier layer 700 may include a chemical vapor deposition (CVD) process to provide step coverage. It should be noted that when depositing the barrier layer 700, since the barrier material will also be deposited between the conductive units U, the barrier material (bottom barrier layer 700b) will also be deposited on the dielectric layer 200. Barrier material (side barrier layer 700s) will also be deposited on the object structure 300′. Moreover, since the barrier material has poor step coverage, it will be sealed at the half of upper portion of the conductive structure 600, and the barrier material deposited above the air gap G is regarded as the top barrier layer 700t. In some embodiments, the air gap G has a protrusion Gp (that is, the top barrier layer has a recess). In some embodiments, top barrier layer 700t has a thickness that is thicker than bottom barrier layer 700b and side barrier layer 700s.

Compared with the prior art where dielectric materials are filled between conductive structures, the embodiments of the present invention may further reduce capacitance between conductive structures by patterning the spacer material into a wing-like shape and providing air gaps between conductive structures.

Compared with the prior art where a sacrificial layer was first formed to ensure an air gap, the embodiments of the present invention may directly form an air gap through a barrier layer with poor step coverage, thereby reducing the number of masks and simplifying the process complexity.

Following the above, the semiconductor device as shown in FIG. 8 may include a substrate 100 and a plurality of conductive units U disposed on the substrate 100. Each conductive unit U includes a conductive structure 600 disposed on the substrate 100 and a pair of spacer structures 300″ disposed on both sides of the conductive structure 600. Each spacer structure 300″ includes a first spacer layer 310″, a second spacer layer 320″ disposed on the first spacer layer 310″, and a second spacer layer 320″ disposed on the first spacer layer 310″, and the fourth spacer layer 340′ disposed on the second spacer layer 320″. The first spacer layer 310″, the second spacer layer 320″, and the fourth spacer layer 340′ respectively include different materials. The semiconductor device may also include an air gap G between each conductive unit U. The semiconductor device may further include a top barrier layer 700t disposed on the conductive unit U, a side barrier layer 700s disposed on the spacer structure 300″ of the conductive unit U, and a bottom barrier layer 700b disposed on the barrier layer 700 on the substrate 100. The top barrier layer 700t covers all of the top surface of each conductive unit U and a portion of the side surfaces of each conductive unit U.

In addition, after the semiconductor device according to the embodiment of the present invention is formed, other components such as metal layers and dielectric layers may still be formed.

In summary, the embodiments of the present invention may also reduce the RC delay in the conductive units through the air gap formed between the conductive units. In addition, in embodiments of the present invention, by including three different materials in the spacer structure, the supporting force of the conductive structure may be increased and the problem of short-circuits between conductive structures may be reduced at the same time. In addition, the embodiments of the present invention may increase the supporting force by using a semiconductor material as one of the spacer layers, and since it has high etching selectivity during the etching process, it will be beneficial to the formation, transfer, and removal of patterns during the process. In addition, by forming the fourth spacer layer including oxide after forming the conductive structure, the embodiments of the present invention may reduce problems with the material of the conductive structure diffusing into the oxide and causing a short-circuit.

Although the present invention is disclosed in the foregoing embodiments, they are not intended to limit the present invention. Those with ordinary skill in the technical field to which the present invention belongs can make some modifications and modifications without departing from the spirit and scope of the present invention. Therefore, the protection scope of the present invention shall be determined by the appended patent application scope.

What is claimed is:

1. A semiconductor device, comprising:
a substrate;
a plurality of conductive units disposed on the substrate, wherein each conductive unit comprises:
a conductive structure disposed on the substrate; and
a pair of spacer structures disposed along both sides of the conductive structure, wherein each spacer structure comprises:
a first spacer layer disposed on the substrate;
a second spacer layer disposed on the first spacer layer;
a third spacer layer disposed on the second spacer layer,
wherein the first spacer layer, the second spacer layer and the third spacer layer each comprise different materials; and
a plurality of air gaps disposed between each conductive unit.

2. The semiconductor device as claimed in claim 1, wherein the first spacer layer comprises a semiconductor material, and the second spacer layer and the third spacer layer comprise different dielectric materials.

3. The semiconductor device as claimed in claim 2, wherein the first spacer layer comprises polycrystalline silicon, the second spacer layer comprises nitride, and the third spacer layer comprises oxide.

4. The semiconductor device as claimed in claim 2, wherein the third spacer layer has a width that is narrow at top and wide at bottom.

5. The semiconductor device as claimed in claim 2, wherein the third spacer layer has a width that becomes wider toward the substrate.

6. The semiconductor device as claimed in claim 1, wherein each air gap has a protrusion.

7. The semiconductor device as claimed in claim 1, further comprising a barrier layer disposed on the substrate, wherein the barrier layer comprises:
a top barrier layer disposed on each conductive unit;
a side barrier layer disposed on the pair of spacer structure of each conductive unit; and
a bottom barrier layer disposed on the substrate.

8. The semiconductor device as claimed in claim 7, wherein the top barrier layer covers an entire top surface of each conductive unit and a portion of a side surface of each conductive unit.

9. The semiconductor device as claimed in claim 7, wherein the top barrier layer is thicker than the bottom barrier layer and the side barrier layer.

10. The semiconductor device as claimed in claim 1, wherein the barrier layer is nitride.

11. The semiconductor device as claimed in claim 1, further comprising a dielectric layer disposed on the substrate, wherein the conductive structure of each conductive unit penetrates through the dielectric layer and contacts the substrate.

12. The semiconductor device as claimed in claim 1, wherein the conductive structure of each conductive unit comprises a metal layer and a block layer surrounding the metal layer.

13. The semiconductor device as claimed in claim 1, wherein the spacer structures are wing-like.

14. A method for forming a semiconductor device, comprising:
providing a substrate;
sequentially forming a spacer stack layer comprising a first spacer predetermined layer, a second spacer predetermined layer and a third spacer predetermined layer on the substrate;
patterning the spacer stack layer to form a plurality of spacer predetermined structures and a plurality of trenches;
forming a plurality of conductive structures in the plurality of trenches;
patterning the plurality of spacer predetermined structures to form a plurality of spacer structures on sidewalls of the plurality of conductive structures, wherein patterning the plurality of spacer predetermined structures comprises:
replacing the third spacer predetermined layer with a plurality of fourth spacer layers; and
using the plurality of fourth spacer layers as masks, etching the second spacer predetermined layer and the first spacer predetermined layer; and
forming a barrier layer on the substrate after forming the plurality of spacer structures, wherein the barrier comprises an air gap.

15. The method as claimed in claim 14, wherein replacing the third spacer predetermined layer with a plurality of fourth spacer layers comprises:
removing the third spacer predetermined layer;
forming a fourth spacer material layer on the second spacer predetermined layer and the conductive structure; and
removing the fourth spacer material layer on the second spacer predetermined layer and top surfaces of the plurality of conductive structures to form the plurality of fourth spacer layer. cm 16. The method as claimed in claim 14, further comprising:
forming a dielectric layer on the substrate before forming the spacer stack layer; and
patterning the dielectric layer and extending the plurality of trenches to contact the substrate.

17. The method as claimed in claim 14, wherein patterning the plurality of spacer predetermined structures further comprises:
using the first spacer predetermined layer as an etch stop layer, using the fourth spacer layer as an etching mask, and etching the second spacer predetermined layer.

18. The method as claimed in claim 14, wherein forming the barrier layer on the substrate comprises a chemical vapor deposition process.

19. The method as claimed in claim 14, wherein the second spacer predetermined layer is nitride and the plurality of fourth spacer layers is oxide.

20. The method as claimed in claim 14, wherein the ratio of a thickness of the first spacer predetermined layer to a thickness of the third spacer predetermined layer is between 1:0.6-1:1.4.
